(19) United States
(12) Patent Application Publication
(10) Pub. No.: US 2026/0047491 A1
(43) Pub. Date: Feb. 12, 2026

(54) SEMICONDUCTOR PACKAGE AND PACKAGE ON PACKAGE INCLUDING THE SAME

(71) Applicant: SAMSUNG ELECTRONICS CO., LTD., Suwon-si (KR)

(72) Inventors: JEONGSEOK KIM, Suwon-si (KR); JIHYUN LEE, Suwon-si (KR); TAE WOOK KIM, Suwon-si (KR); HYUNGMIN KIM, Suwon-si (KR); JOOYOUNG CHOI, Suwon-si (KR); SANGSEOK HONG, Suwon-si (KR)

(73) Assignee: SAMSUNG ELECTRONICS CO., LTD., Suwon-si (KR)

(21) Appl. No.: 19/076,487

(22) Filed: Mar. 11, 2025

(30) Foreign Application Priority Data
Aug. 9, 2024 (KR) 10-2024-0106757

(51) Int. Cl. H01L 25/18; H01L 23/00; H01L 23/498; H01L 23/538; H01L 25/065; H10B 80/00; H10D 80/30

(52) U.S. Cl. CPC H01L 25/18; H01L 23/49811; H01L 23/49833; H01L 23/5383; H01L 23/562; H01L 24/24; H01L 24/48; H01L 25/0655; H10B 80/00; H10D 80/30; H01L 2224/24137; H01L 2224/48229; H01L 2924/1431

(57) ABSTRACT

A semiconductor package includes: a redistribution structure; a semiconductor chip on the redistribution structure and electrically connected to the redistribution structure; an encapsulant encapsulating at least a portion of the semiconductor chip; one or more conductive pads on the encapsulant and electrically connected to the redistribution structure; and a passivation layer on the encapsulant, the passivation layer including an opening exposing a portion of the one or more conductive pads, wherein each of the one or more conductive pads includes: a first edge area covered by the passivation layer; and a second edge area exposed by the opening of the passivation layer and separated from the passivation layer.

### CROSS-REFERENCE TO RELATED APPLICATION

This application claims priority to Korean Patent Application No. 10-2024-0106757, filed on Aug. 9, 2024, in the Korean Intellectual Property Office, the disclosure of which is incorporated by reference herein in its entirety.

### BACKGROUND

### 1. Field

The present disclosure relates to a semiconductor package and a package on package including the same.

### 2. Description of Related Art

In electronic products such as mobile devices, various types of semiconductor packages are used to integrate various functions into a single device. Among these semiconductor packages, a package on package (POP) is a method of vertically stacking an application processor (AP) package and a memory package, and has a merit of increasing a performance while efficiently utilizing a space. Recently, with an increasing demand for high performance and high capacity of POP, semiconductor chips with various sizes and structures are being applied in the package, and there is a demand for a reduction in a gap of solder balls used for an electrical connection between the AP package and the memory package.

### SUMMARY

One or more embodiments provide a semiconductor package that may prevent electric shorts between conductive bumps by controlling a solder flow and a package on package including the same may be provided.

According to an aspect of the disclosure, a semiconductor package includes: a redistribution structure; a semiconductor chip on the redistribution structure and electrically connected to the redistribution structure; an encapsulant encapsulating at least a portion of the semiconductor chip; one or more conductive pads on the encapsulant and electrically connected to the redistribution structure; and a passivation layer on the encapsulant, the passivation layer including an opening exposing a portion of the one or more conductive pads, wherein each of the one or more conductive pads includes: a first edge area covered by the passivation layer; and a second edge area exposed by the opening of the passivation layer and separated from the passivation layer.

According to an aspect of the disclosure, a semiconductor package includes: a redistribution structure including a first surface and a second surface that are opposite to each other, and the redistribution structure further including a conductive pad on the first surface; a passivation layer on the first surface of the redistribution structure, the passivation layer including an opening that exposes a portion of the conductive pad; a semiconductor chip on the second surface of the redistribution structure; an encapsulant on the second surface of the redistribution structure and encapsulating at least a portion of the semiconductor chip; and a conductive bump on the passivation layer and filling at least a portion of the opening, wherein the conductive pad includes: a first edge area covered by the passivation layer; and a second edge area exposed by the opening of the passivation layer and separated from the passivation layer.

According to an aspect of the disclosure, a package on package includes: a first semiconductor package including: a first redistribution structure; a first semiconductor chip on the first redistribution structure; a first encapsulant encapsulating at least a portion of the first semiconductor chip; a first conductive pad on the first encapsulant and electrically connected to the first redistribution structure; and a first passivation layer on the first encapsulant, the first passivation layer including a first opening exposing a portion of each of the first conductive pad; and a second semiconductor package on the first semiconductor package, the second semiconductor package including: a second redistribution structure including a first surface and a second surface that are opposite to each other, the second redistribution structure further including a second conductive pad on the first surface; a second passivation layer on the first surface of the second redistribution structure, the second passivation layer including a second opening exposing a portion of the second conductive pad; a conductive bump on the second passivation layer; a second semiconductor chip on the second surface of the second redistribution structure; and a second encapsulant on the second surface of the second redistribution structure and encapsulating at least a portion of the second semiconductor chip, wherein the first conductive pad includes: a first edge area covered by the first passivation layer; and a second edge area exposed by the first opening of the first passivation layer and separated from the first passivation layer, and wherein the conductive bump fills at least part of each of the first opening and the second opening.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a cross-sectional view of a package on package (POP) according to a comparative example;

FIG. 2 is a view showing a shape of warpage that occurs in a package on package according to a comparative example;

FIG. 3 is a view showing a shape of an electric short of a conductive bump that occurs in an actual product;

FIG. 4 is a cross-sectional view of a semiconductor package according to an embodiment of the disclosure;

FIG. 5 is a top view of a semiconductor package shown in FIG. 4;

FIG. 6 is an enlarged view of an area A of FIG. 4;

FIG. 7 is an enlarged view of an example variation of an area A of FIG. 4;

FIG. 8 is an enlarged view of an area B of FIG. 5;

FIG. 9 is a cross-sectional view of a package on package including a semiconductor package illustrated in FIG. 4;

FIG. 10 is a view showing an occurrence of a warpage in a package on package illustrated in FIG. 9;

FIG. 11 is a cross-sectional view of a semiconductor package according to an embodiment of the disclosure;

FIG. 12 is a cross-sectional view of a semiconductor package according to an embodiment of the disclosure;

FIG. 13 is a cross-sectional view of a semiconductor package according to an embodiment of the disclosure;

FIG. 14 is a cross-sectional view of a semiconductor package according to an embodiment of the disclosure;

FIG. 15 is an enlarged view of an area C of FIG. 14;

FIG. 16 is an enlarged view of an example variation of the area C of FIG. 14;

FIG. 17 is a cross-sectional view of a package on package including a semiconductor package illustrated in FIG. 14;

FIG. 18 is a view showing an occurrence of a warpage in a package on package illustrated in FIG. 17; and

FIG. 19 to FIG. 30 are views illustrating a manufacturing method of a semiconductor package illustrated in FIG. 12.

### DETAILED DESCRIPTION

Non-limiting example embodiments of the disclosure will be described more fully hereinafter with reference to the accompanying drawings, in which example embodiments of the disclosure are shown. As those skilled in the art would realize, the described exampled embodiments may be modified in various different ways, all without departing from the spirit and scope of the disclosure.

In order to clearly explain example embodiments of the disclosure, portions that are not directly related to embodiments may be omitted, and the same reference numerals are attached to the same or similar constituent elements through the entire specification.

In addition, a size and thickness of each configuration shown in the drawings may be arbitrarily shown for better understanding and ease of description, but embodiments of the disclosure are not limited thereto. In the drawings, a thickness of layers, films, panels, areas, etc., may be exaggerated for clarity. In the drawings, for better understanding and ease of description, thicknesses of some layers and areas may be exaggerated.

Throughout this specification and the claims that follow, when it is described that an element is “coupled” to another element, the element may be “directly coupled” to the other element or “indirectly coupled” to the other element through a third element. From a similar perspective, this includes not only being “physically connected” but also being “electrically connected.”

It will be understood that when an element such as a layer, film, area, or substrate is referred to as being “on” another element, it can be directly on the other element or intervening elements may also be present. In contrast, when an element is referred to as being “directly on” another element, there are no intervening elements present. Further, in the specification, the word “on” or “above” does not necessarily mean positioned on the upper side of the object portion based on a gravitational direction.

In addition, unless explicitly described to the contrary, the word “comprise” (or “include”), and variations such as “comprises” (or “includes”) or “comprising” (or “including”), will be understood to imply the inclusion of stated elements but not the exclusion of any other elements.

Further, in the specification, the phrase “on a plane” means viewing the object portion from the top, and the phrase “on a cross-section” means viewing a cross-section, of which the object portion is vertically cut, from the side.

Additionally, throughout the specification, the sequential numbers, such as “first,” “second,” etc., are used to distinguish a component from other identical or similar components, and are not necessarily intended to refer to a specific component. Thus, a component referred to as a first component in a particular part of this specification may be referred to as a second component in another part of this specification.

Additionally, throughout the specification, a singular reference to any component includes a plurality of references to that component, unless otherwise stated. For example, “insulating layer” may be used to mean not only one insulating layer, but also a plurality of insulating layers, such as two, three or more.

Additionally, throughout the specification, references to directions such as an upper surface, an upper, an upper side, an upper, a lower surface, a lower side, a lower etc., are provided with reference to the drawings to aid explanation and understanding.

Hereinafter, semiconductor packages according to non-limiting example embodiments of the disclosure are described with reference to the drawings.

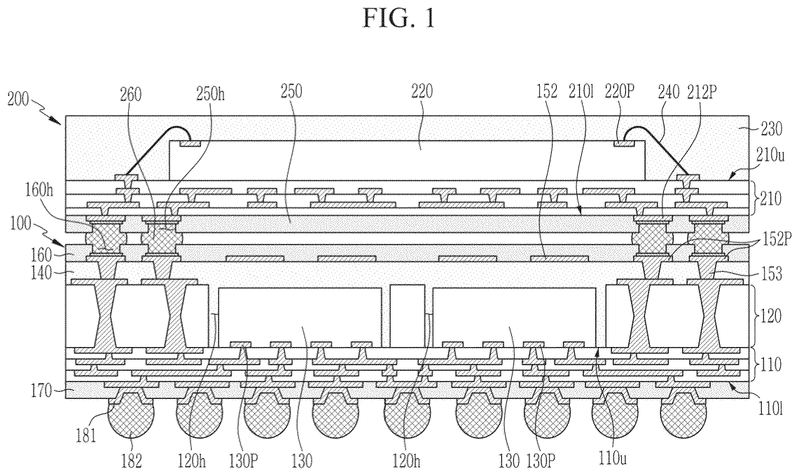

FIG. 1 is a cross-sectional view of a package on package (POP) according to a comparative example.

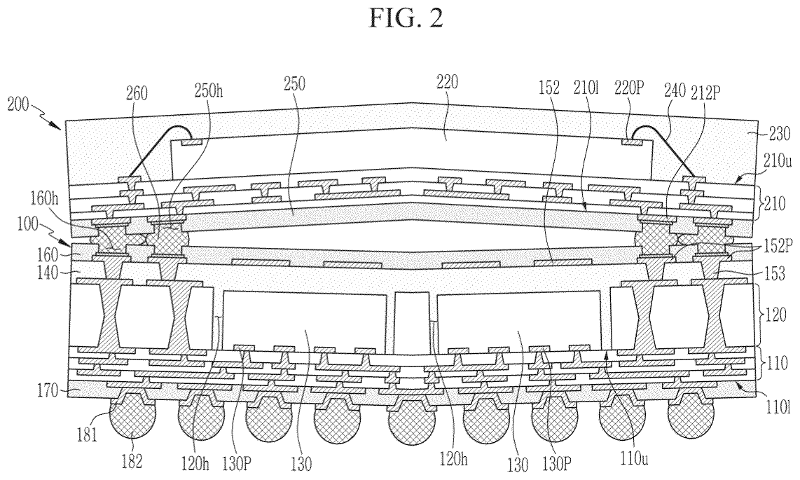

FIG. 2 is a view showing a shape of a warpage that occurs in a package on package according to a comparative example.

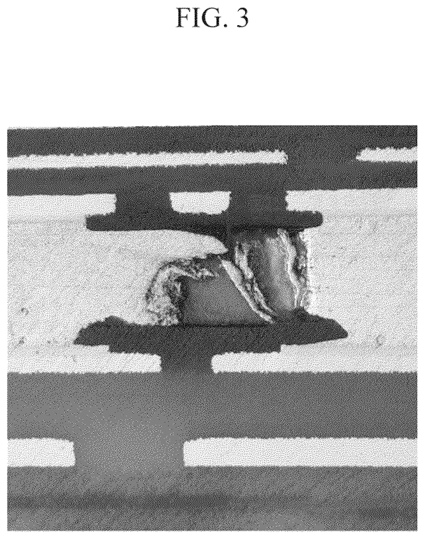

FIG. 3 is a view showing a shape of an electric short of a conductive bump that occurs in an actual product.

Referring to FIG. 1, a package on package (POP) may include a first semiconductor package 100 as a lower package, and a second semiconductor package 200 as an upper package. The first semiconductor package 100 and the second semiconductor package 200 may be connected via conductive bumps 260 (e.g., solder balls), and the first semiconductor package 100 and the second semiconductor package 200 may include conductive pads 152P and 212P (e.g., copper (Cu) pads), respectively, for a connection to the conductive bumps 260. SMD pads may be used as the conductive pads 152P and 212P of the first semiconductor package 100 and the second semiconductor package 200.

There are two types of conductive pads: a solder mask defined (SMD) pad and a non-solder mask defined (NSMD) pad. The SMD pad has a structure in which the opening of the solder mask is formed smaller than the pad diameter, so that the edge area is covered by the solder mask. On the other hand, the NSMD pad forms the solder mask larger than the pad diameter, so that the edge area is separated from the Cu pad.

Referring to FIG. 2, a warpage phenomenon in which the semiconductor packages bend may occur due to a difference in a thermal expansion coefficient (CTE) between the first semiconductor package 100 and the second semiconductor package 200 in the POP. For example, the first semiconductor package 100 may be bent into a frown shape in which a central area protrudes upward, and the second semiconductor package 200 may be bent into a smile shape in which the central area protrudes downward. When the warpage occurs, the adjacent solder balls may become pressurized, causing an electric short between them (referring to FIG. 3). Additionally, when the solder balls in the POP edge area are pressurized, the thickness of the center area of the POP may become thicker, causing a problem that deviates from reference specifications.

Embodiments of the disclosure introduce a half non-solder mask defined (NSMD) pad that combines the SMD pad and the NSMD pad into the semiconductor package to control a solder flow and prevent electric shorts from occurring when the adjacent solder balls come into contact with each other when the warpage occurs. In addition, embodiments of the disclosure alleviate the problem of the maximum thickness of the POP increasing due to the pressurization of the solder balls. The half NSMD pad according to embodiments of the disclosure may be introduced into at least one of the first semiconductor package 100 and the second semiconductor package 200.

Hereinafter, semiconductor packages according to embodiments of the disclosure, including the half NSMD pad, are described in detail.

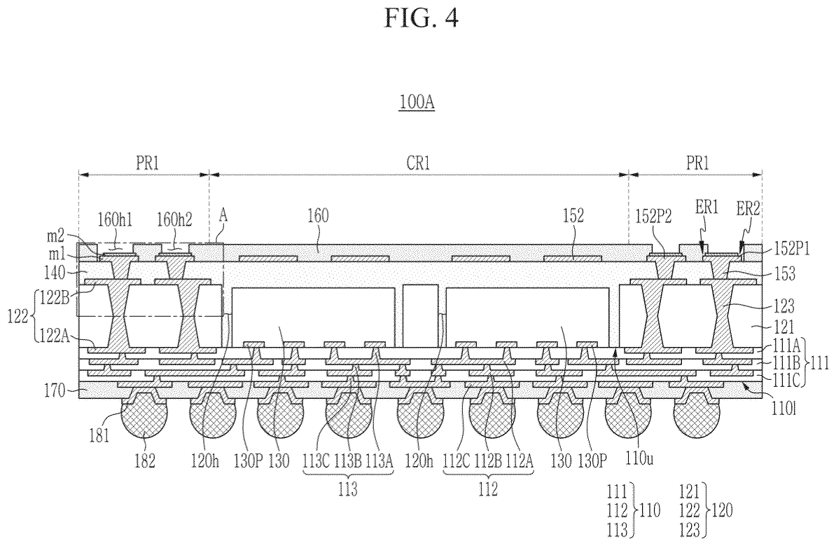

FIG. 4 is a cross-sectional view of a semiconductor package according to an embodiment of the disclosure.

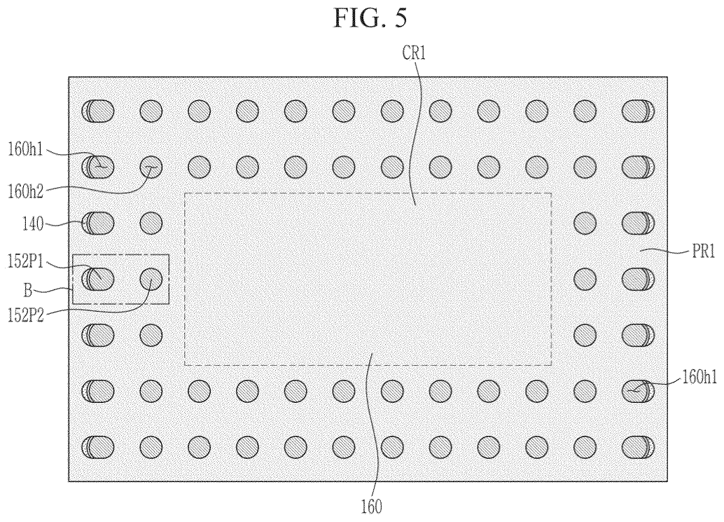

FIG. 5 is a top view of a semiconductor package shown in FIG. 4.

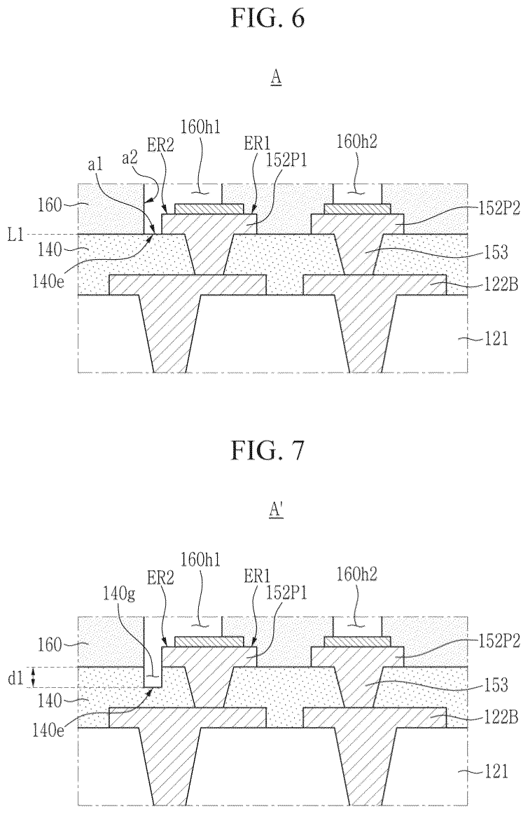

FIG. 6 is an enlarged view of an area A of FIG. 4.

FIG. 7 is an enlarged view of an example variation of an area A of FIG. 4.

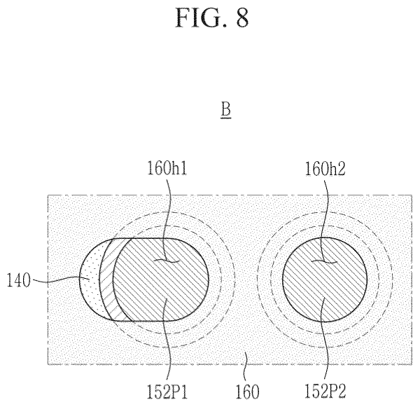

FIG. 8 is an enlarged view of an area B of FIG. 5.

In an embodiment, the half NSMD pad may be introduced into the first semiconductor package, which is a lower package of the package on package.

The first semiconductor package 100A may include a redistribution structure 110, a core substrate 120 disposed on the redistribution structure 110 and having a through hole 120h, a semiconductor chip 130 disposed on the redistribution structure 110 within the through hole 120h, an encapsulant 140 encapsulating at least a part of the semiconductor chip 130 and extending on the core substrate 120, one or more conductive pads (e.g., a first conductive pad 152P1 and a second conductive pad 152P2) disposed on the encapsulant 140, and a passivation layer 160 disposed on the encapsulant 140 and having openings (e.g., a first opening 160h1 and a second opening 160h2) exposing a partial area of the conductive pads (e.g., the first conductive pad 152P1 and the second conductive pad 152P2).

The redistribution structure 110 may include an insulating layer(s) 111, a wiring layer(s) 112, and a via(s) 113. For example, the redistribution structure 110 may include a first insulating layer 111A, a first wiring layer 112A disposed on the first insulating layer 111A, first vias 113A electrically connecting the first wiring layer 112A to the semiconductor chip 130 and the core substrate 120, respectively, by penetrating the first insulating layer 111A, a second insulating layer 111B disposed on the first insulating layer 111A and covering the second wiring layer 112B, a second wiring layer 112B disposed on the second insulating layer 111B, second vias 113B connecting the first wiring layer 112A and the second wiring layer 112B by penetrating the second insulating layer 111B, a third insulating layer 111C on the second insulating layer 111B and covering the second wiring layer 112B, a third wiring layer 112C disposed on the third insulating layer 111C, and third vias 113C penetrating the third insulating layer 111C to connect the second wiring layer 112B and the third wiring layer 112C.

The redistribution structure 110 may have an upper surface 110u and a lower surface 1101, and the upper surface 110u of the redistribution structure 110 may be a surface at which the first insulating layer 111A is arranged, and the lower surface 1101 may be a surface at which the third insulating layer 111C and the third wiring layer 112C are arranged.

The insulating layer 111 may be placed between the wiring layers 112 to prevent electric shorts between them. The insulating layers 111 may have boundaries with each other or may not have boundaries that may be seen with the naked eye, depending on the materials and manufacturing processes thereof. An insulating material can be used as the material of the insulating layer 111 and may, for example, be polyimide (PI), epoxy, photo-imageable dielectric (PID), etc.

The wiring layer 112 may include wire pattern(s), and the wire patterns may be connected to each other to perform various functions depending on a configuration. For example, the wiring layer 112 may include at least one from among a signal pattern performing a signal transmission function, a power pattern performing a power transfer function, and a ground pattern performing a ground function. A third wiring layer 112C, located at the bottom of the wiring layers 112, may include conductive pads for the electrical connection with conductive bumps 182. The number of the wiring layers 112 is not limited and may be more or less than a number shown in the drawings. A conductive material may be used as the material of wiring layer 112, and examples thereof include copper (Cu), aluminum (Al), gold (Au), silver (Ag), platinum (Pt), tin (Sn), chromium (Cr), palladium (Pd), lead (Pb), titanium (Ti), tungsten (W), or an alloy thereof.

The via 113 may provide an electrical connection between the wiring layers 112 positioned on different layers. The first vias 113A located at the top may be in contact with the semiconductor chip 130 and the core substrate 120, respectively, to electrically connect them to the wiring layer 112. A conductive material may be used as the material for the via 113, and the same material as the material for wiring layer 112 may be used. Depending on the manufacturing process, the via 113 may be integrally formed with the wiring layer 112, so that no boundary exists between them. Additionally, the via 113 may have a tapered shape, a circular cylinder shape, etc., with a width becoming narrower from one side to the other.

The core substrate 120 may be placed on the upper surface 110u of the redistribution structure 110.

The core substrate 120 may provide an electrical connection between the redistribution structure 110 and the wiring layer 152 including the conductive pads (e.g., the first conductive pad 152P1 and the second conductive pad 152P2). Therefore, the core substrate 120 may be electrically connected to each of the redistribution structure 110 and the wiring layer 152.

The core substrate 120 may have a through hole 120h. The through hole 120h may penetrate between the upper and lower surfaces of the core substrate 120. In an embodiment, the first semiconductor package 100A may include a plurality of semiconductor chips 130, and the core substrate 120 may include a plurality of through holes 120h for the placement of each of the semiconductor chips 130.

The core substrate 120 may include an insulating layer(s) 121, a wiring layer(s) 122, and a via(s) 123. For example, the core substrate 120 may include an insulating layer 121, a first wiring layer 122A disposed on the lower surface of the insulating layer 121, a second wiring layer 122B disposed on the upper surface of the insulating layer 121, and a via 123 penetrating the insulating layer 121 to electrically connect the first wiring layer 122A and the second wiring layer 122B. According to some example embodiments of the disclosure, an additional build-up layer(s) including an insulating layer and a wiring layer may be placed on the upper surface and/or lower surface of the insulating layer 111.

The insulating layer 121 may provide rigidity to the core substrate 120 and may prevent electric shorts between the wiring layers 122. As the material of the insulating layer 121, an insulating material may be used such as, for example, polyimide (polyimide; PI), epoxy (epoxy), prepreg (prepreg), etc.

The wiring layer 122 may include wire pattern(s), and the wire patterns may be connected to each other to perform various functions depending on a configuration. For example, the wiring layer 112 may include at least one from among a signal pattern performing a signal transmission function, a power pattern performing a power transfer function, and a ground pattern performing a ground function. Depending on the manufacturing process, the first wiring layer 122A may or may not be at least partially embedded within the first insulating layer 111A of the redistribution structure 110. A conductive material may be used as the material of the wiring layer 122 such as, for example, copper (Cu), aluminum (Al), gold (Au), silver (Ag), platinum (Pt), tin (Sn), chromium (Cr), palladium (Pd), lead (Pb), titanium (Ti), tungsten (W), or an alloy thereof.

The via 123 may provide an electrical connections between the wiring layers 122 positioned on different layers. A conductive material may be used as the material for the via 123, and the same material as the material for wiring layer 122 may be used. Depending on the manufacturing process, the via 123 may be integrally formed with wiring layer 122, so that no boundary exists between them. Additionally, the via 123 may have an hourglass shape, a tapered shape, a circular cylinder shape, etc., with a width that becomes narrower from one side to the other.

According to an embodiment, the conductive pads (e.g., the first conductive pad 152P1 and the second conductive pad 152P2) may be electrically connected to the redistribution structure 110 via a conductive post, a conductive ball, or the like, replacing the core substrate 120, and such an embodiment should also be considered to be included in the present disclosure.

The semiconductor chip 130 may be placed on the upper surface 110u of the redistribution structure 110 within the through hole 120h and be electrically connected to the redistribution structure 110. The first semiconductor package 100A may include a plurality of semiconductor chips 130, and each semiconductor chip 130 may be placed within each through hole 120h.

The semiconductor chip 130 may include a connection pad 130P, and the connection pad 130P may be arranged in a face down configuration so as to face the redistribution structure 110. The semiconductor chip 130 may be connected by being in contact with the redistribution structure 110, but is not limited thereto, and may also be connected through other configurations such as conductive bumps.

The semiconductor chip 130 may include a logic chip. The logic chip may include one or more from among an application processor (AP), a microprocessor, a central processing unit (CPU), a graphic processing unit (GPU), a neural processing unit (NPU), an application specific integrated circuit (ASIC), and a system on chip (SoC).

According to some embodiments of the disclosure, the semiconductor chips 130 may further include a power management IC (PMIC) chip. For example, the semiconductor chips 130 may be composed of a plurality of semiconductor chips including a logic chip and a PMIC chip.

The encapsulant 140 may encapsulate at least a portion of the semiconductor chip 130 and may extend onto the core substrate 120. Additionally, the encapsulant 140 may fill a portion (e.g., an area where the semiconductor chip 130 is not placed) of the through hole 120h. As the material for the encapsulant 140, an insulating materials such as Ajinomoto Build-up Film (ABF) and Epoxy Molding Compound (EMC) may be used.

The conductive pads (e.g., the first conductive pad 152P1 and the second conductive pad 152P2) may be placed on the encapsulant 140 and can be electrically connected to the core substrate 120. The conductive pads (e.g., the first conductive pad 152P1 and the second conductive pad 152P2) may be arranged in a fan out area (i.e., an area that does not overlap the semiconductor chip 130 in the vertical direction) but is not limited thereto.

The conductive pads may include a first conductive pad 152P1 and a second conductive pad 152P2.

The first conductive pad 152P1 may be a half NSMD pad according to some embodiments of the disclosure. The first conductive pad 152P1 may include a first edge area ER1 (similar to an SMD pad) covered by the passivation layer 160 and a second edge area ER2 (similar to an NSMD pad) exposed by the first opening 160h1 of the passivation layer 160 and spaced from the passivation layer 160.

In an embodiment, the second conductive pad 152P2 may be an SMD pad. The edge area of the second conductive pad 152P2 may be covered with the passivation layer 160, and the center area of the second conductive pad 152P2 surrounded by the edge area may be exposed by the second opening 160h2 of the passivation layer 160. In another embodiment, the second conductive pad 152P2 may be an NSMD pad.

According to some embodiments of the disclosure, by selectively placing the first conductive pad 152P1 in the area of the semiconductor package where the solder flow control is required, the adjacent ones of the conductive bumps 260 may be prevented from coming into contact with each other and causing an electric short when the warpage occurs. In addition, the problem of the maximum thickness of POP becoming thicker due to the pressurization of the conductive bumps 260 may be alleviated.

When the warpage occurs, the first conductive pads 152P1 may be placed on each portion of a peripheral area PR1 on both sides of the first semiconductor package 100A as both sides (or four sides) of the first semiconductor package 100A are bent in the same direction. For example, referring to FIG. 4 and FIG. 5 together, the first conductive pads 152P1 may be spaced apart from each other and a central area CR1, which is in between the peripheral area PR1. In other words, some of the first conductive pads 152P1 may be arranged on a left portion of the peripheral area PR1 of the first semiconductor package 100A and others of the first conductive pads 152P1 may be arranged on a right portion of the peripheral area PR1. According to some embodiments of the disclosure, the first conductive pads 152P1 may be arranged to be around the central area CR1 along the peripheral area PR1 of the first semiconductor package 100A.

In an embodiment, for each of the first conductive pads 152P1 arranged on both sides of the peripheral area PR1 of the first semiconductor package 100A, the first edge area ER1 may be arranged towards (e.g., adjacent to) the center area CR1. In other words, each of the first conductive pads 152P1 arranged on the peripheral area PR1 on both sides of the first semiconductor package 100A may be arranged so that the second edge area ER2 is towards the outside of the first semiconductor package 100A. By arranging the second edge area ER2 of the first conductive pad 152P1 toward the outside of the first semiconductor package 100A, the solder flow may be controlled in the outside direction of the first semiconductor package 100A.

To prevent the electric short with other conductive pads placed on the outside of the first conductive pad 152P1, the first conductive pad 152P1 may be placed on the outermost side of the first semiconductor package 100A among the conductive pads (e.g., the first conductive pad 152P1 and the second conductive pad 152P2). For example, the first conductive pad 152P1 may be placed more outward than the second conductive pad 152P2 in the first semiconductor package 100A.

In the present disclosure, the central area CR1 and the peripheral area PR1 of the first semiconductor package 100A are described as being distinct from each other, but this is only to describe an example position where the conductive pads (e.g., the first conductive pad 152P1 and the second conductive pad 152P2) are arranged, and the central area CR1 and the peripheral area PR1 may not have clearly distinct boundaries.

Referring to FIG. 6, the first opening 160h1 may expose an area 140e of the encapsulant 140 that is adjacent to the second edge area ER2. Additionally, a wall surface a2 of the first opening 160h1 may be spaced from the second edge area ER2 of the first conductive pad 152P1.

The side of the first conductive pad 152P1 may be exposed in the second edge area ER2 through the first opening 160h1. The exposed side may be combined with the conductive bump 260, and the bonding force and reliability between the first conductive pad 152P1 and the conductive bump 260 may be improved.

In an embodiment, the first opening 160h1 may be formed by machining the passivation layer 160 to the interface between the passivation layer 160 and the encapsulant 140. Therefore, a bottom surface a1 of the first opening 160h1 may be positioned at a level L1 which is substantially the same as the upper surface of the encapsulant 140. In the present disclosure, “substantially the same” means not only the case where it is completely the same, but also includes an error range in the process. By positioning the bottom surface a1 of the first opening 160h1 and the top surface of the encapsulant 140 at substantially the same level, the contact area between the conductive bump 260 and the first conductive pad 152P1 may be maximized while securing the sufficient solder flow control space.

The width of the first opening 160h1 may be narrower in the direction toward the floor surface a1, may be the same, or may be wider in some cases. In addition, the shape of the first opening 160h1 on a plane is not particularly limited, and may have a shape such as an oval, a quadrangle with rounded corners, etc.

Referring to FIG. 7, in another embodiment, the encapsulant 140 may have a groove portion 140g extending from a first opening 160h1. The groove portion 140g may be formed by further processing a portion of the encapsulant 140 during the formation of the first opening 160h1. A depth d1 of the groove portion 140g may be equal to or less than 10 μm. If the depth d1 of the groove portion 140g exceeds 10 μm, the area in contact with encapsulant 140 of the conductive bump 260 may widen, resulting in a weakened bonding strength. According to some embodiments of the disclosure, a metal (e.g., Cu) pattern functioning as a machining stop layer may be placed within the encapsulant 140 to control the depth d1 of the groove portion 140g.

A conductive material may be used as the material of the first conductive pad 152P1 and the second conductive pad 152P2 and may be, for example, copper (Cu), aluminum (Al), gold (Au), silver (Ag), platinum (Pt), tin (Sn), chromium (Cr), palladium (Pd), lead (Pb), titanium (Ti), tungsten (W), or their alloys.

Referring again to FIG. 4, the conductive pads (e.g., the first conductive pad 152P1 and the second conductive pad 152P2) may be composed of a plurality of metal layers such as, for example, a first metal layer m1 and a second metal layer m2 disposed on the first metal layer m1. The first metal layer m1 may include copper (Cu), and the thickness of the first metal layer m1 may be approximately 10 μm. The second metal layer m2 may improve the reliability of the conductive pads (e.g., the first conductive pad 152P1 and the second conductive pad 152P2) and prevent a corrosion. The second metal layer m2 may include a plurality of layers such as, for example, a nickel (Ni) layer and a gold (Au) layer on the nickel layer. The thickness of the second metal layer m2 may be about 5 μm to 6 μm, and/or the diameter of the second metal layer m2 may be formed to be smaller than the diameter of the first metal layer m1, but is not limited thereto.

The conductive pads (e.g., the first conductive pad 152P1 and the second conductive pad 152P2) may be configured to be included in the wiring layer 152 disposed on the encapsulant 140. The wiring layer 152 may further include a wire patterns in addition to the conductive pads (e.g., the first conductive pad 152P1 and the second conductive pad 152P2). The wire pattern may include at least one from among a signal pattern performing a signal transmission function, a power pattern performing a power transfer function, and a ground pattern performing a ground function. The same material as the conductive pad 152P may be used for the wiring layer 152. The wire patterns other than the conductive pads (e.g., the first conductive pad 152P1 and the second conductive pad 152P2) of the wiring layer 152 may include only the first metal layer m1 and may not include the second metal layer m2. The first semiconductor package 100A may further include a connection via 153 for electrically connecting the conductive pads (e.g., the first conductive pad 152P1 and the second conductive pad 152P2) and the core substrate 120. The connection via 153 may penetrate a portion of the encapsulant 140 and be in contact with the conductive pads (e.g., the first conductive pad 152P1 and the second conductive pad 152P2) and the core substrate 120, respectively. For example, the connection via 153 may be connected to the second wiring layer 122B of the core substrate 120. The same material as the wiring layer 152 may be used for the material of the connection via 153.

The passivation layer 160 may be disposed on the encapsulant 140 and have openings (e.g., the first opening 160h1 and the second opening 160h2) exposing some areas of the conductive pads (e.g., the first conductive pad 152P1 and the second conductive pad 152P2). For example, the passivation layer 160 may have a first opening 160h1 exposing a portion of the first conductive pad 152P1, and a second opening 160h2 exposing a portion of the second conductive pad 152P2. The first opening 160h1 may be formed of a larger size than a size of the second opening 160h2 in order to expose the second edge area ER2 of the first conductive pad 152P1. As the material for the passivation layer 160, insulating materials such as a solder mask and an ABF may be used.

The first semiconductor package 100A may further include a passivation layer 170 disposed on the lower surface 1101 of the redistribution structure 110. The passivation layer 170 may have an opening that exposes a conductive pad included in the third wiring layer 112C located at the bottom of the redistribution structure 110. As the material for the passivation layer 170, insulating materials such as a solder mask and an ABF may also be used.

Additionally, the first semiconductor package 100A may further include a conductive bump 182 disposed on the passivation layer 170 on the lower surface 1101 of the redistribution structure 110 to electrically connect the first semiconductor package 100A to other components such as a main board. The conductive bump 182 may fill the opening in the passivation layer 170 and be electrically connected to the redistribution structure 110. The conductive bump 182 may be, for example, a solder ball. The number, spacing, and arrangement of the conductive bumps 182 are not particularly limited and may be implemented in various forms.

According to some embodiments, an under bump metallurgy (UBM) layer 181 may be formed between the conductive bump 182 and the redistribution structure 110. The UBM layer 181 may play a role in improving the bonding strength between the redistribution structure 110 and the conductive bump 182 and performing the function of a diffusion barrier. According to some embodiments, the UBM layer 181 may be configured of a plurality of layers.

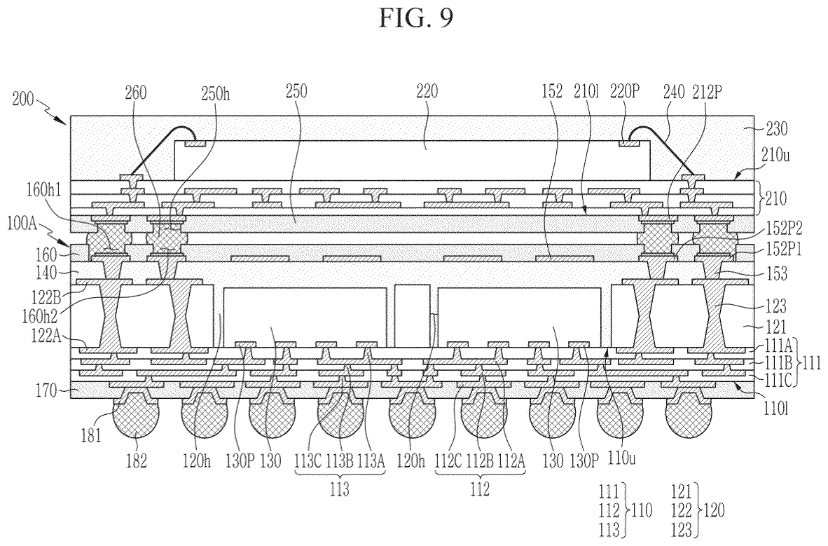

FIG. 9 is a cross-sectional view of a package on package including a semiconductor package illustrated in FIG. 4.

The package on package may include a first semiconductor package 100A according to an embodiment, and a second semiconductor package 200 disposed on the first semiconductor package 100A and electrically connected to the first semiconductor package 100A.

The second semiconductor package 200 may include a redistribution structure 210 including a conductive pad 212P disposed at the lower surface of the redistribution structure 210, a semiconductor chip 220 disposed on the upper surface of the redistribution structure 210, an encapsulant 230 encapsulating at least a portion of the semiconductor chip 220 on the upper surface of the redistribution structure 210, a passivation layer 250 arranged on the lower surface of the redistribution structure 210 and having an opening 250h exposing a part area of the conductive pad 212P, and a conductive bump 260 disposed on the passivation layer 250.

The conductive bump 260 may electrically connect the second semiconductor package 200 to the first semiconductor package 100A. The conductive bump 260 may fill at least part of each of the openings (e.g., the first opening 160h1 and the second opening 160h2) of the passivation layer 160 of the first semiconductor package 100A and the opening 250h of the passivation layer 250 of the second semiconductor package 200, and may be connected to the conductive pads (e.g., the first conductive pad 152P1 and the second conductive pad 152P2) of the first semiconductor package 100A and the conductive pad 212P of the second semiconductor package 200, respectively. According to embodiments of the present disclosure, the solder flow may be controlled when forming the conductive bump 260 by introducing the first conductive pad 152P1. In an embodiment, the solder flow may be controlled in the outward direction from the package on package.

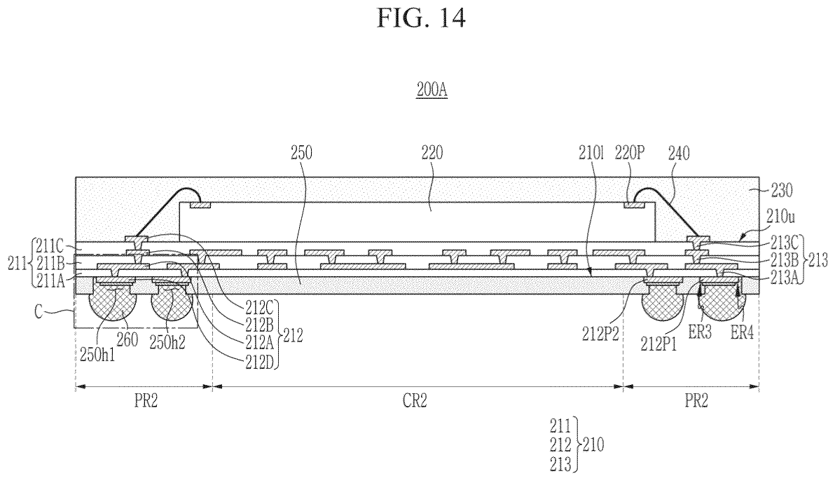

Other configurations of the second semiconductor package 200 are described in detail below with reference to FIG. 14.

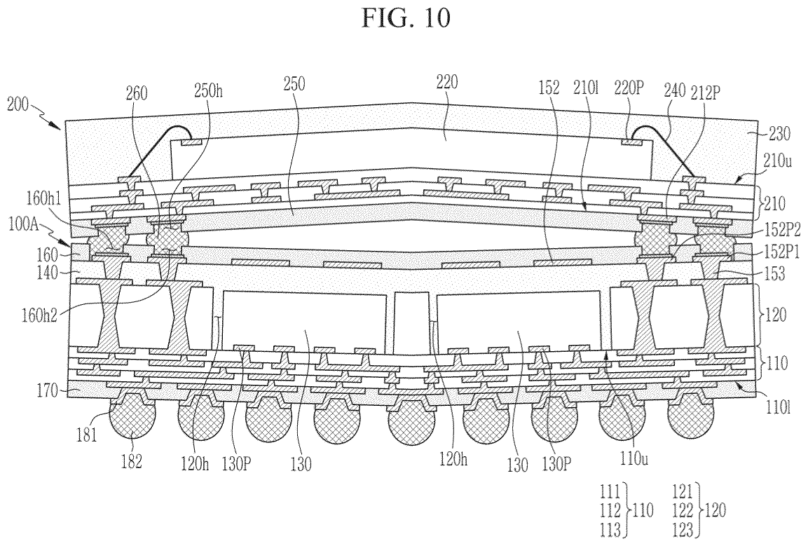

FIG. 10 is a view showing an occurrence of a warpage in a package on package illustrated in FIG. 9.

According to embodiments of the present disclosure, by selectively placing the first conductive pad 152P1 in an area where the control of the solder flow is required, the adjacent ones of the conductive bumps 260 may be prevented from coming into contact with each other and causing an electric short when the warpage occurs. In addition, the problem that the maximum thickness of POP is thicker due to the pressurization of conductive bumps 260 may be alleviated.

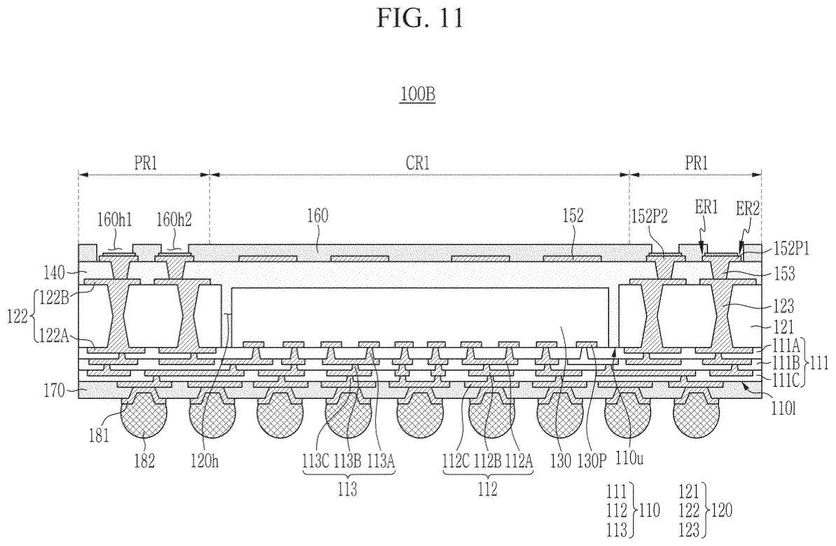

FIG. 11 is a cross-sectional view of a semiconductor package according to an embodiment.

The second semiconductor package 100B may include a single through hole 120h and a single semiconductor chip 130.

For other configurations of the second semiconductor package 100B, the same provisions as described above for the first semiconductor package 100A may be applied unless otherwise specifically contradictory.

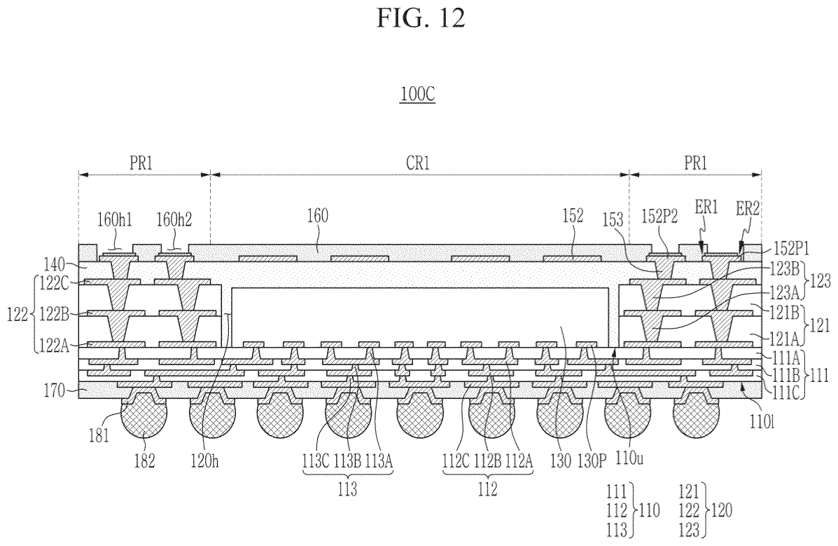

FIG. 12 is a cross-sectional view of a semiconductor package according to an embodiment.

The semiconductor package 100C may have a core substrate 120 with an embedded trace substrate (ETS) structure. For example, the core substrate 120 may include a first wiring layer 122A, a first insulating layer 121A covering the first wiring layer, a second wiring layer 122B disposed on the first insulating layer 121A, a first via 123A electrically connecting the first wiring layer 122A and the second wiring layer 122B by penetrating the first insulating layer 121A, a second insulating layer 121B disposed on the first insulating layer 121A and covering the second wiring layer 122B, a third wiring layer 122C disposed on the second insulating layer 121B, and a second via 123B electrically connecting the second wiring layer 122B and the third wiring layer 122C by penetrating the second insulating layer 121B.

For other configurations of the semiconductor package 100C, the above-descriptions may be equally applied for the description of the first semiconductor package 100A and the second semiconductor package 100B, unless specifically contradictory.

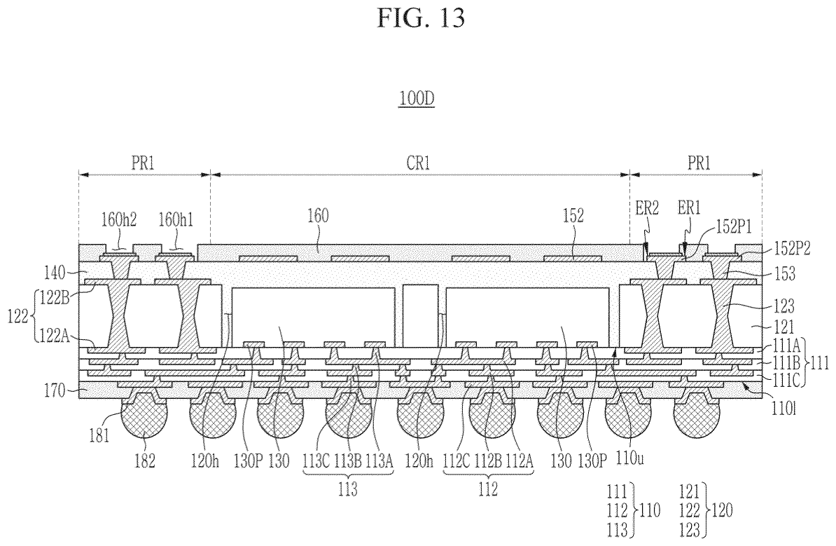

FIG. 13 is a cross-sectional view of a semiconductor package according to an embodiment.

For each of the first conductive pads 152P1 arranged on the portions of the peripheral area PR1 on both sides of the semiconductor package 100D, the second edge area ER2 may be arranged towards (e.g., adjacent to) the center area CR1. In other words, each of the first conductive pads 152P1 arranged on the portions of the peripheral area PR1 on both sides of the semiconductor package 100D may be arranged so that the second edge area ER2 faces the inside of the semiconductor package 100D. By arranging the second edge area ER2 of the first conductive pad 152P1 toward the inside of the semiconductor package 100D, the solder flow may be controlled in the inward direction of the semiconductor package 100D.

To prevent the electric short with other conductive pads placed on the inner side of the first conductive pad 152P1, the first conductive pad 152P1 may be placed on the innermost side of the semiconductor package 100D among The conductive pads (e.g., the first conductive pad 152P1 and the second conductive pad 152P2). For example, the first conductive pad 152P1 may be placed further than the second conductive pad 152P2 inside the semiconductor package 100D.

For other configurations of the semiconductor package 100D, the same provisions as described above for the first semiconductor package 100A may be applied unless otherwise specifically contradictory.

FIG. 14 is a cross-sectional view of a semiconductor package according to an embodiment.

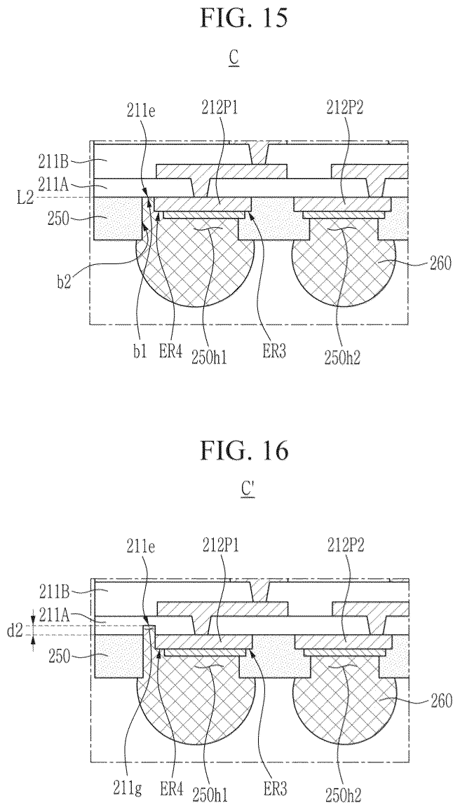

FIG. 15 is an enlarged view of an area C of FIG. 14.

FIG. 16 is an enlarged view of an example variation of the area C of FIG. 14.

In an embodiment, the half NSMD pad may be introduced into a second semiconductor package, which is an upper package of the package on package.

The second semiconductor package 200A may include a redistribution structure 210 including conductive pads (e.g., the third conductive pad 212P1 and the fourth conductive pad 212P2) disposed on the lower surface of the redistribution structure 210, a semiconductor chip 220 disposed on the upper surface 210u of the redistribution structure 210, an encapsulant 230 encapsulating at least a part of the semiconductor chip 220 on the upper surface 210u of the redistribution structure 210, a passivation layer 250 disposed on the lower surface 2101 of the redistribution structure 210 and having openings (e.g., the third opening 250h1 and the fourth opening 250h2) exposing partial areas of the conductive pads (e.g., the third conductive pad 212P1 and the fourth conductive pad 212P2), and a conductive bump 260 disposed on the passivation layer 250.

The redistribution structure 210 may include insulating layer(s) 211, wiring layer(s) 212, and via(s) 213. For example, the redistribution structure 210 may include a first insulating layer 211A, a first wiring layer 212A disposed on the upper surface of the first insulating layer 211A, a second insulating layer 211B disposed on the first insulating layer 211A and covering the first wiring layer 212A, a second wiring layer 212B disposed on the second insulating layer 211B, a third insulating layer 211C disposed on the second insulating layer 211B and covering the second wiring layer 212B, a third wiring layer 212C disposed on the third insulating layer 211C, a fourth wiring layer 212D disposed on the lower surface of the first insulating layer 211A, a first via 213A penetrating the first insulating layer 211A to connect the first wiring layer 212A and the fourth wiring layer 212D, a second via 213B penetrating the second insulating layer 211B to connect the second wiring layer 212B and the third wiring layer 212C, and a third via 213C penetrating the third insulating layer 211C to connect the third wiring layer 212C and the fourth wiring layer 212D.

The upper surface 210u of the redistribution structure 210 may be a surface at which the third insulating layer 211C and the third wiring layer 212C are arranged, and the lower surface 2101 of the redistribution structure 210 may be a surface at which the first insulating layer 211A and the fourth wiring layer 212D are arranged.

The insulating layers 211 may be placed between the wiring layers 212 to prevent electric shorts between them. The insulating layers 211 may have boundaries with each other or may not have boundaries that can be seen with the naked eye, depending on materials and manufacturing processes thereof. An insulating material may be used as the material of the insulating layer 211 such as, for example, polyimide (PI), epoxy, Photo-Imageable Dielectric (PID), etc., may be used.

The wiring layer 212 may include a wire pattern(s), and the wire patterns may be connected to each other to perform various functions depending on the configuration. For example, the wiring layer 212 may include at least one from among a signal pattern performing a signal transmission function, a power pattern performing a power transfer function, and a ground pattern performing a ground function. The third wiring layer 212C positioned at the top among the wiring layers 212, and the fourth wiring layer 212D positioned at the bottom among the wiring layers 212 may include conductive pads for the electrical connection with the semiconductor chip 220 and the conductive bumps 260, respectively. The number of the wiring layers 212 is not limited and may be more or less than the number shown in the drawings. A conductive material may be used as the material of the wiring layer 212, and examples thereof include copper (Cu), aluminum (Al), gold (Au), silver (Ag), platinum (Pt), tin (Sn), chromium (Cr), palladium (Pd), lead (Pb), titanium (Ti), tungsten (W) or an alloy thereof.

The vias 213 may provide an electrical connection between the wiring layers 212 positioned on different layers. A conductive material may be used as the material for the via 213, and the same material as the material for the wiring layer 212 may be used. According to the manufacturing process, the via 213 may be integrally formed with the wiring layer 212, so that no boundary exists between them. Additionally, the via 213 may have a tapered shape that becomes narrower from one side to the other, a circular cylinder shape, etc.

The conductive pads may include a third conductive pad 212P1 and a fourth conductive pad 212P2.

The third conductive pad 212P1 may be a half NSMD pad according to embodiments of the present disclosure. The third conductive pad 212P1 may include a third edge area ER3 covered by the passivation layer 250, and a fourth edge area ER4 exposed by the third opening 250h1 of the passivation layer 250 and spaced from the passivation layer 250.

In an embodiment, the fourth conductive pad 212P2 may be an SMD pad. The edge area of the fourth conductive pad 212P2 may be covered by the passivation layer 250, and the center area of the fourth conductive pad 212P2 surrounded by the edge area may be exposed by the fourth opening 250h2 of the passivation layer 250. In another embodiment, the fourth conductive pad 212P2 may be an NSMD pad.

When the warpage occurs, two sides (or four sides) of the second semiconductor package 200A may be warped in the same direction, so that the third conductive pads 212P1 may be placed on each portion of the peripheral area PR2 on both sides of the second semiconductor package 200A. For example, some of the third conductive pads 212P1 may be spaced apart from each other via a central area CR2 in the peripheral area PR2. According to some embodiments, the third conductive pads 212P1 may be arranged to be around the central area CR2 along the peripheral area PR2 of the second semiconductor package 200A.

In an embodiment, each of the third conductive pads 212P1 arranged on both portions of peripheral area PR2 of the second semiconductor package 200A may have a third edge area ER3 arranged towards (e.g., adjacent to) the center area CR2. At this time, in order to prevent an electric short with other conductive pads placed on the outside of the third conductive pad 212P1, the third conductive pad 212P1 may be placed on the outermost side of the second semiconductor package 200A among the conductive pads (e.g., the third conductive pad 212P1 and the fourth conductive pad 212P2). For example, the third conductive pad 212P1 may be placed more outward than the fourth conductive pad 212P2 in the second semiconductor package 200A.

In another embodiment, each of the third conductive pads 212P1 arranged on both portions of the peripheral area PR2 of the second semiconductor package 200A may have a fourth edge area ER4 arranged towards (e.g., adjacent to) the center area CR2. At this time, in order to prevent an electric short with other conductive pads placed on the inner side of the third conductive pad 212P1, the third conductive pad 212P1 may be placed on the innermost side of the second semiconductor package 200A among the conductive pads (e.g., the third conductive pad 212P1 and the fourth conductive pad 212P2). For example, the third conductive pad 212P1 may be placed further than the fourth conductive pad 212P2 inside the second semiconductor package 200A.

Meanwhile, the second semiconductor package 200A, the central area CR2, and the peripheral area PR2 may not have clearly distinct boundaries.

Referring to FIG. 15, the third opening 250h1 may expose an area 211e adjacent to the fourth edge area ER4 of the first insulating layer 211A. Additionally, a wall surface b2 of the third opening 250h1 may be spaced from the fourth edge area ER4 of the third conductive pad 212P1.

The side of the third conductive pad 212P1 in the fourth edge area ER4 may be exposed through the third opening 250h1. The exposed side may be combined with the conductive bump 260, and the bonding strength and reliability between the third conductive pad 212P1 and the conductive bump 260 may be improved.

In an embodiment, the third opening 250h1 may be formed by machining the passivation layer 250 up to the interface between the passivation layer 250 and the first insulating layer 211A. Therefore, a bottom surface b1 of the third opening 250h1 may be positioned at substantially a same level L2 as the lower surface of the first insulating layer 211A. By positioning the bottom surface b1 of the third opening 250h1 and the lower surface of the first insulating layer 211A at substantially the same level, the contact area between the conductive bump 260 and the third conductive pad 212P1 may be maximized while sufficiently securing the solder flow control space.

The width of the third opening 250h1 may be narrower in the direction toward the bottom surface b1, may be the same, or may be wider in some cases. In addition, the shape of the third opening 250h1 on the plane is not particularly limited, and may have a shape such as an oval, a quadrangle with rounded corners, etc.

Referring to FIG. 16, in another embodiment, the first insulating layer 211A may have a groove portion 211g extending from the third opening 250h1. The groove portion 211g may be formed by further processing a portion of the first insulating layer 211A when forming the third opening 250h1. A depth d2 of the groove portion 211g may be equal to or less than 10 μm. If the depth d2 of the groove portion 211g exceeds 10 μm, the area in contact with the first insulating layer 211A of the conductive bump 260 may expand, thereby weakening the bonding strength. According to some embodiments, a metal (e.g., Cu) pattern functioning as a machining stop layer may be placed within the first insulating layer 211A to control the depth d2 of the groove portion 211g.

The semiconductor chip 220 may be placed on the upper surface 210u of the redistribution structure 210 and be electrically connected to the redistribution structure 210. The semiconductor chip 220 may include a connection pad 220P and may be arranged in a face up orientation so that the connection pad 220P may face upward to be bonded via a conductive wire 240. Alternatively, the semiconductor chip 220 may be placed in a face down orientation so that the connection pad 220P may face downward. The number of semiconductor chips 220 is not particularly limited, and may be singular or a plurality of semiconductor chips.

The semiconductor chip 220 may include a memory chip. The memory chip may include one or more of a dynamic random access memory (DRAM) chip, a static random access memory (SRAM) chip, a flash memory chip, a high bandwidth memory (HBM) chip, a read-only memory (ROM) chip, and a magnetic random access memory (MRAM) chip.

The encapsulant 230 may encapsulate at least a portion of the semiconductor chip 220 on the upper surface 210u of the redistribution structure 210. As the material for encapsulant 230, insulating materials such as an Ajinomoto build-up film (ABF) and an epoxy molding compound (EMC) may be used.

The passivation layer 250 may be disposed on the lower surface 2101 of the redistribution structure 210 and may have openings (e.g., the third opening 250h1 and the fourth opening 250h2) exposing some areas of the conductive pads (e.g., the third conductive pad 212P1 and the fourth conductive pad 212P2). For example, the passivation layer 250 may have a third opening 250h1 exposing a portion of the third conductive pad 212P1, and a fourth opening 250h2 exposing a portion of the fourth conductive pad 212P2. The third opening 250h1 may be formed with a larger size than the fourth opening 250h2 in order to expose the fourth edge area ER4 of the third conductive pad 212P1. Insulating materials such as a solder mask and ABF may be used as the material for the passivation layer 250.

The conductive bump 260 may be arranged on the passivation layer 250 to electrically connect the second semiconductor package 200A to the first semiconductor package 100. The conductive bump 260 may fill at least part of the openings (e.g., the third opening 250h1 and the fourth opening 250h2) of the passivation layer 250 and be electrically connected to the redistribution structure 210. The conductive bump 260 may be for example a solder ball. The number, spacing, and arrangement of the conductive bumps 260 are not particularly limited and may be implemented in various forms.

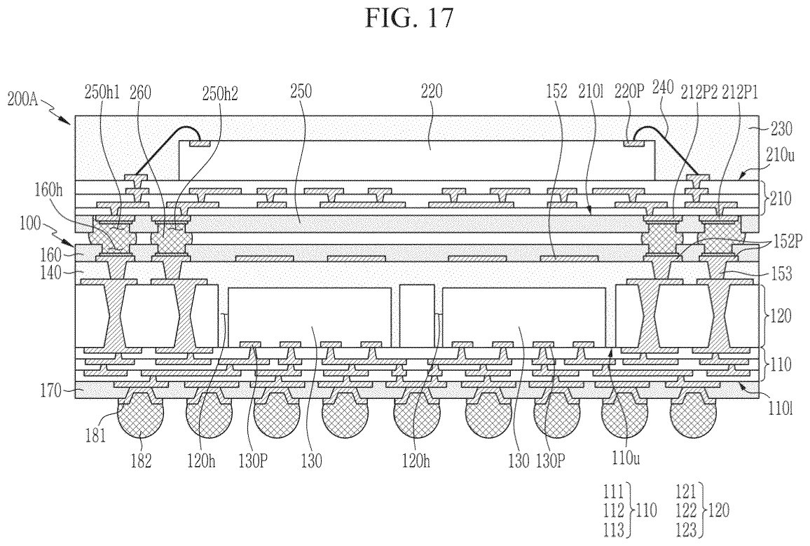

FIG. 17 is a cross-sectional view of a package on package including the semiconductor package illustrated in FIG. 14.

The package on package may include a first semiconductor package 100 and a second semiconductor package 200A according to an embodiment.

The conductive bump 260 may electrically connect the second semiconductor package 200A with the first semiconductor package 100. The conductive bump 260 may fill at least a portion of each of the opening 160h of the passivation layer 160 of the first semiconductor package 100 and the openings (e.g., the third opening 250h1 and the fourth opening 250h2) of the passivation layer 250 of the second semiconductor package 200A, and be connected to the conductive pad 152P of the first semiconductor package 100 and the conductive pads (e.g., the third conductive pad 212P1 and the fourth conductive pad 212P2) of the second semiconductor package 200A. According to embodiments of the present disclosure, the solder flow may be controlled when forming the conductive bump 260 by introducing the third conductive pad 212P1. In an embodiment, the solder flow may be controlled in the outward direction of the package on package.

According to an embodiment, the first semiconductor package 100 may be composed of semiconductor packages (e.g., the first semiconductor package 100A, the second semiconductor packager100B, the semiconductor package 100C, and the semiconductor package 100D) including a first conductive pad 152P1. That is, the half NSMD pad according to an embodiment of the present disclosure may be introduced to both the first semiconductor package and the second semiconductor package. At this time, the second edge area ER2 of the first conductive pad 152P1 and the fourth edge area ER4 of the third conductive pad 212P1 may overlap each other in a plane (vertically). By exposing the edge areas ER2 and ER4 of the conductive pads through openings (e.g., a first opening 160h1 and a third opening 250h1) at the overlapping positions, the solder flow may be controlled in the same direction.

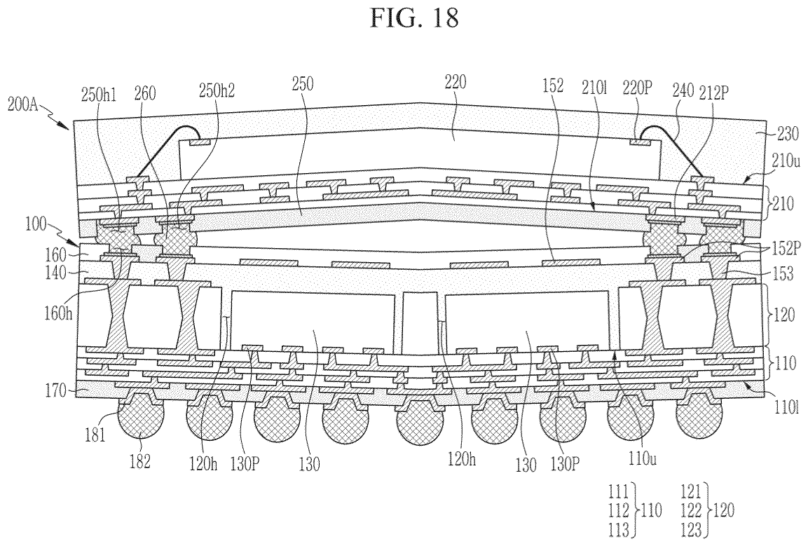

FIG. 18 is a view showing an occurrence of a warpage in a package on package illustrated in FIG. 17.

According to embodiments of the present disclosure, by selectively placing a third conductive pad 212P1 in an area where the solder flow control is required, it may prevent the adjacent conductive bumps 260 from being connected to each other and causing the electric short when the warpage occurs. In addition, the problem of the maximum thickness of the POP becoming thicker due to the pressurization of the conductive bumps 260 may be alleviated.

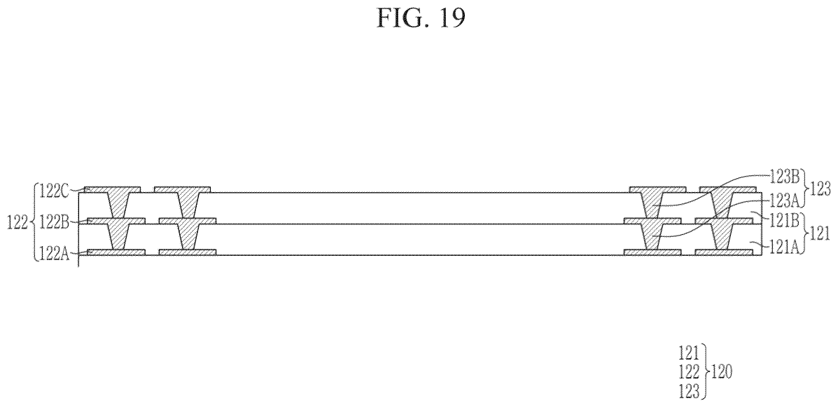

FIG. 19 to FIG. 30 are views illustrating a manufacturing method of a semiconductor package illustrated in FIG. 12.

In the following description, the manufacturing method of the semiconductor package 100C is described as an example.

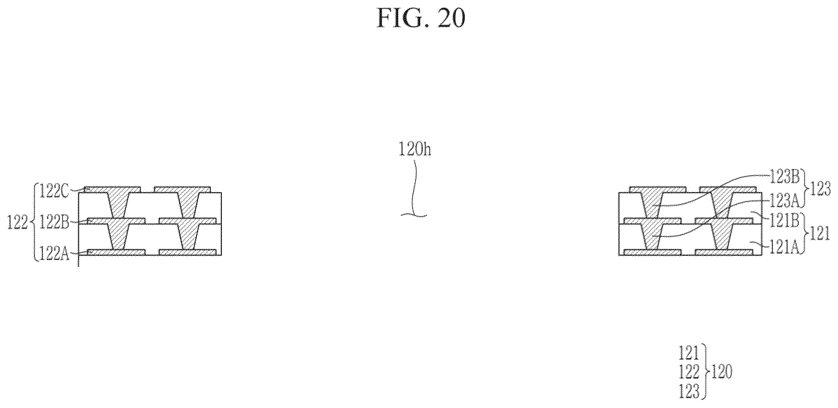

First, referring to FIG. 19 and FIG. 20, a core substrate 120 may be formed, and then a through hole 120h may be formed in the core substrate 120. The core substrate 120 may be manufactured by sequentially forming a wiring layer(s) 122, an insulating layer(s) 121, and a via(s) 123. The formation method of the through hole 120h is not particularly limited, and may be formed by a laser processing, a mechanical processing, etc.

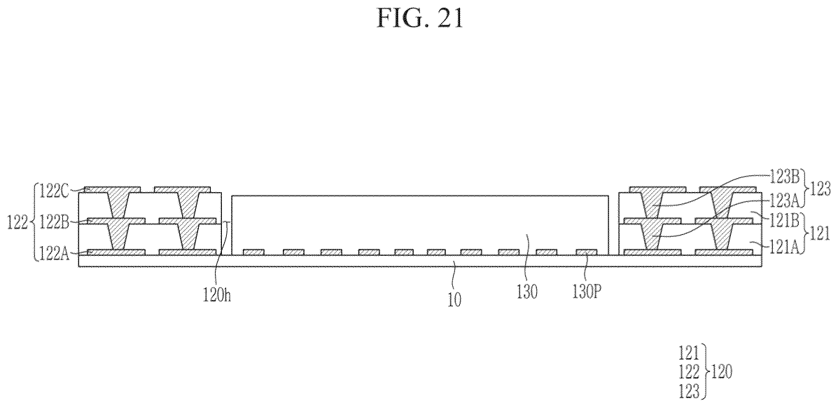

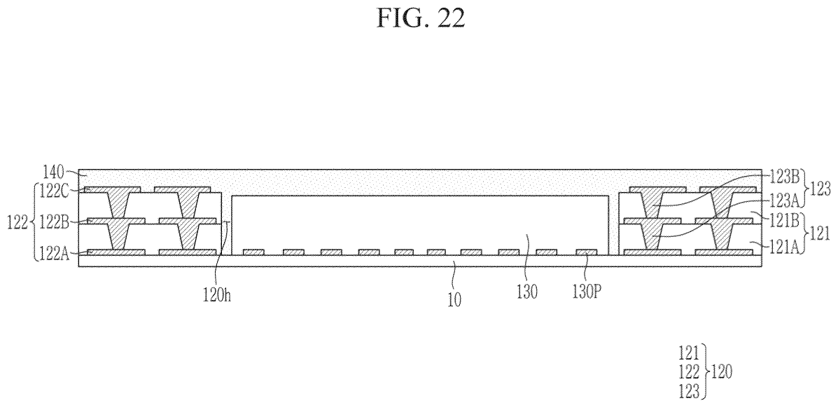

Next, referring to FIG. 21 and FIG. 22, a semiconductor chip 130 may be placed within the through hole 120h of the core substrate 120, and an encapsulant 140 may be formed. The semiconductor chip 130 may be fixed by attaching an adhesive member 10, such as a die attach film (DAF), to the lower surface of the core substrate 120 and attaching it to the adhesive member 10 within the through hole 120h of the core substrate 120. The forming method of the encapsulant 140 is not particularly limited, and may be formed by a compression molding, a transfer molding, etc.

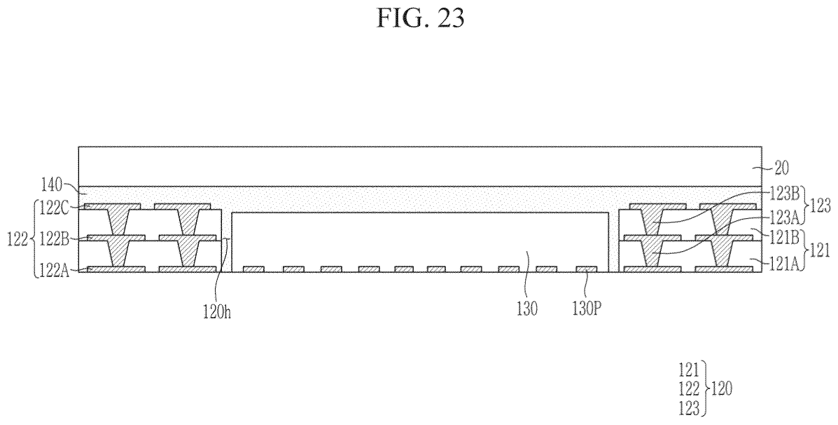

Next, referring to FIG. 23, the encapsulant 140 may be attached to a first carrier structure 20 and the adhesive member 10 may be removed. The adhesive member 10 may be removed by a heat treatment, ultraviolet rays treatment, etc.

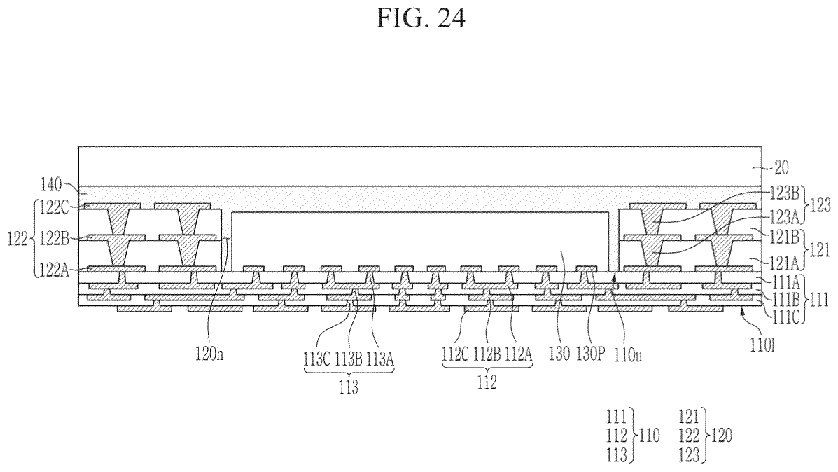

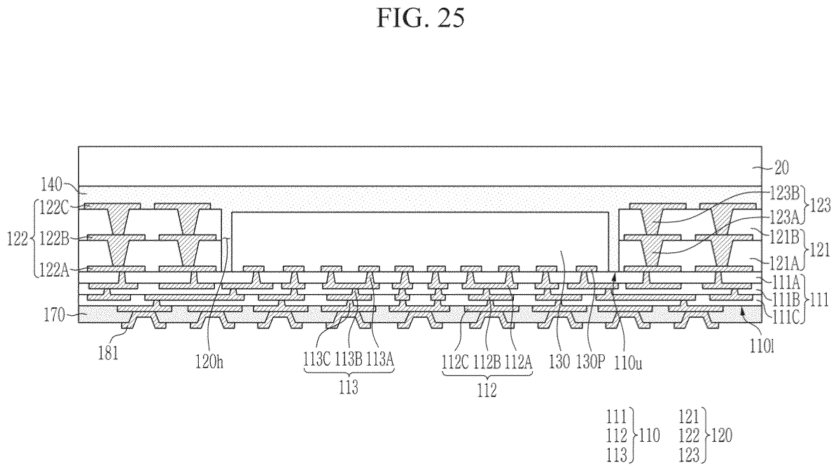

Next, referring to FIG. 24 and FIG. 25, a redistribution structure 110 may be formed on the surface from which the adhesive member 10 of the core substrate 120 and the semiconductor chip 130 is removed, and a passivation layer 170 and a UBM layer 181 may be formed on the redistribution structure 110. The redistribution structure 110 may be manufactured by sequentially forming an insulating layer(s) 111, a via(s) 113, and a wiring layer(s) 112. When a PID is used as the insulating layer 111, the via 113 having a fine pitch may be formed by a photo process.

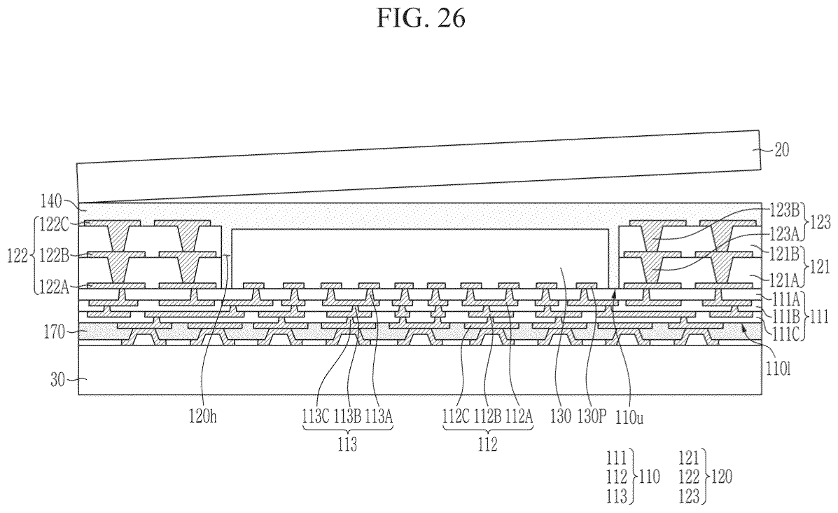

Next, referring to FIG. 26, the first carrier structure 20 may be removed and a second carrier structure 30 may be attached on the lower surface of the redistribution structure 110.

According to some embodiments of the present disclosure, an additional encapsulant may be formed on the encapsulant 140 after removing the first carrier structure 20. The additional encapsulant may be formed by a lamination of, for example, ABF and may be integral with the encapsulant 140 so that they do not have a boundary with each other. The additional encapsulant may be attached in a semi-cured state on the encapsulant 140 in a cured state to improve the bonding strength between the encapsulant 140 and the wiring layer 152.

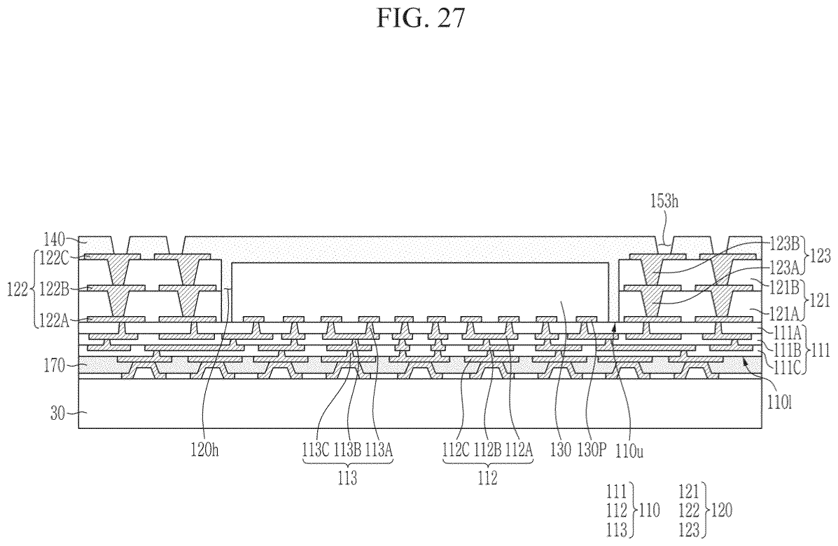

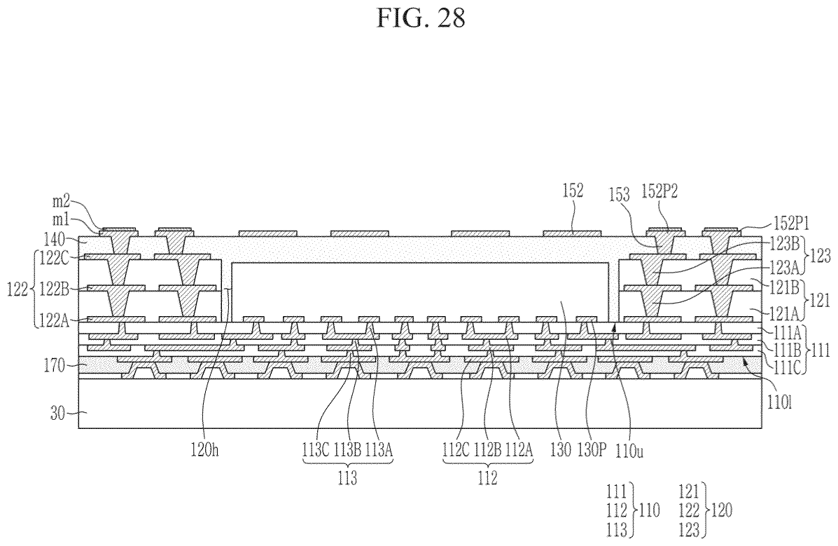

Next, referring to FIG. 27 and FIG. 28, a connection via 153 may be formed, and a wiring layer 152 including conductive pads (e.g., a first conductive pad 152P1 and a second conductive pad 152P2) may be formed. The connection via 153 may be formed by laser-processing the encapsulant 140 to form a via hole 153h and filling the inside of the via hole 153h through a plating process. The wiring layer 152 may be formed on the encapsulant 140 through a plating process and may be integrally formed with the connection via 153. When forming the conductive pads (e.g., the first conductive pad 152P1 and the second conductive pad 152P2), a second metal layer m2 may be additionally formed on the first metal layer m1.

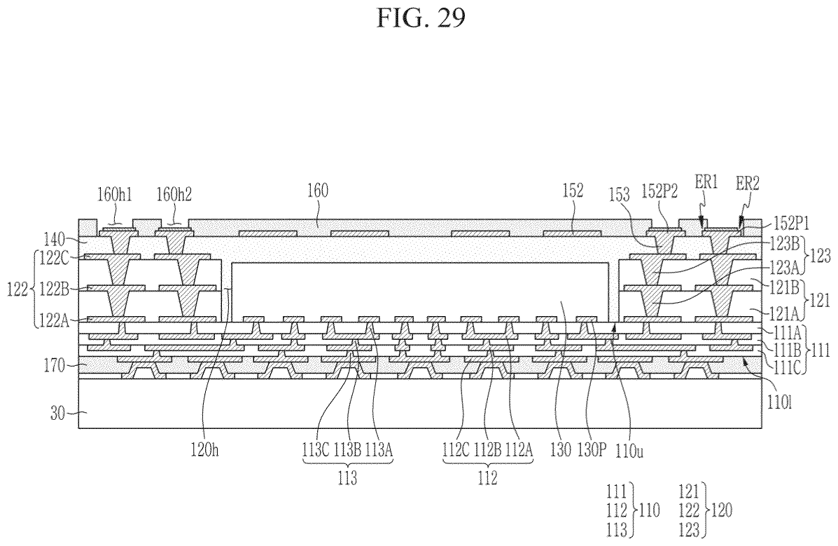

Next, referring to FIG. 29, a passivation layer 160 may be formed to cover the wiring layer 152 on the encapsulant 140, and openings (e.g., the first opening 160h1 and the second opening 160h2) may be formed in the passivation layer 160. The passivation layer 160 may be formed by laminating such as, for example, ABF. The openings (e.g., the first opening 160h1 and the second opening 160h2) may be formed by physically (e.g., laser) or chemically processing the passivation layer 160, and the first opening 160h1 may be formed to expose the second edge area ER2 of the first conductive pad 152P1.

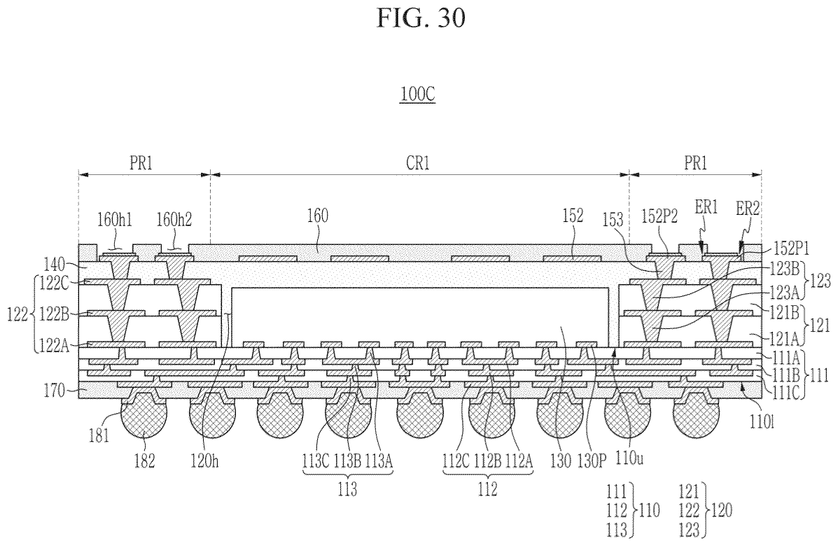

Finally, referring to FIG. 30, the second carrier structure 30 may be removed and a conductive bump 182 may be formed on the UBM layer 181, thereby fabricating the semiconductor package 100C according to an embodiment.

While non-limiting example embodiments have been described, it is to be understood that the present disclosure is not limited to the example embodiments, and, on the contrary, various modifications and equivalent arrangements are included within the spirit and scope of the present disclosures.

Additionally, the example embodiments of the present disclosure are not independent of each other and may be implemented in combination with each other unless they are specifically contradictory. Therefore, combinations of the embodiments of the present disclosure should also be considered as included in the present disclosure.

What is claimed is:

1. A semiconductor package comprising:
a redistribution structure;
a semiconductor chip on the redistribution structure and electrically connected to the redistribution structure;
an encapsulant encapsulating at least a portion of the semiconductor chip;
one or more conductive pads on the encapsulant and electrically connected to the redistribution structure; and
a passivation layer on the encapsulant, the passivation layer including an opening exposing a portion of the one or more conductive pads,
wherein each of the one or more conductive pads comprises:
a first edge area covered by the passivation layer; and
a second edge area exposed by the opening of the passivation layer and separated from the passivation layer.

2. The semiconductor package of claim 1, wherein the opening exposes an area, of the encapsulant, adjacent to the second edge area.

3. The semiconductor package of claim 2, wherein a bottom surface of the opening is at a level that is the same as a level of a top surface of the encapsulant.

4. The semiconductor package of claim 2, wherein the encapsulant includes a groove portion extending from the opening.

5. The semiconductor package of claim 4, wherein a depth of the groove portion is equal to or less than 10 μm.

6. The semiconductor package of claim 1, wherein the semiconductor package comprises a peripheral area and a central area surrounded by the peripheral area, and
wherein the one or more conductive pads comprise a first conductive pad and a second conductive pad that are on the peripheral area, and the first conductive pad and the second conductive pad are spaced apart from each other with the central area interposed between the first conductive pad and the second conductive pad.

7. The semiconductor package of claim 6, wherein the first edge area of each of the first conductive pad and the second conductive pad is at a side of the first conductive pad and the second conductive pad, respectively, that is towards the central area.

8. The semiconductor package of claim 6, wherein the second edge area of each of the first conductive pad and the second conductive pad is at a side of the first conductive pad and the second conductive pad, respectively, that is towards the central area.

9. The semiconductor package of claim 1, further comprising:
a core substrate on the redistribution structure and electrically connected to the redistribution structure, the core substrate including a through hole,
wherein the semiconductor chip is in the through hole.

10. The semiconductor package of claim 9, wherein the core substrate comprises:
an insulating layer comprising a first surface and a second surface that are opposite to each other;
a first wiring layer disposed on the first surface of the insulating layer;
a second wiring layer on the second surface of the insulating layer; and
a via penetrating the insulating layer and electrically connecting the first wiring layer and the second wiring layer.

11. The semiconductor package of claim 9, wherein the core substrate comprises:
a first wiring layer;
a first insulating layer on the first wiring layer;
a second wiring layer on the first insulating layer;
a first via penetrating the first insulating layer and electrically connecting the first wiring layer and the second wiring layer;
a second insulating layer on the first insulating layer and the second wiring layer;
a third wiring layer on the second insulating layer; and
a second via penetrating the second insulating layer and electrically connecting the second wiring layer and the third wiring layer.

12. The semiconductor package of claim 1, wherein a connection pad of the semiconductor chip faces the redistribution structure.

13. The semiconductor package of claim 1, wherein the semiconductor chip is on a first surface of the redistribution structure, and
wherein the semiconductor package further comprises a conductive bump on a second surface of the redistribution structure, opposite to the first surface.

14. A semiconductor package comprising:
a redistribution structure comprising a first surface and a second surface that are opposite to each other, and the redistribution structure further comprising a conductive pad on the first surface;
a passivation layer on the first surface of the redistribution structure, the passivation layer including an opening that exposes a portion of the conductive pad;
a semiconductor chip on the second surface of the redistribution structure;
an encapsulant on the second surface of the redistribution structure and encapsulating at least a portion of the semiconductor chip; and
a conductive bump on the passivation layer and filling at least a portion of the opening,
wherein the conductive pad comprises:
a first edge area covered by the passivation layer; and
a second edge area exposed by the opening of the passivation layer and separated from the passivation layer.

15. The semiconductor package of claim 14, wherein the redistribution structure further comprises an insulating layer,
wherein the insulating layer is on the conductive pad, and
wherein the opening exposes an area of the insulating layer adjacent to the second edge area.

16. The semiconductor package of claim 15, wherein the insulating layer includes a groove portion extending from the opening.

17. A package on package comprising:
a first semiconductor package comprising:
a first redistribution structure;
a first semiconductor chip on the first redistribution structure;
a first encapsulant encapsulating at least a portion of the first semiconductor chip;
a first conductive pad on the first encapsulant and electrically connected to the first redistribution structure; and
a first passivation layer on the first encapsulant, the first passivation layer comprising a first opening exposing a portion of each of the first conductive pad; and
a second semiconductor package on the first semiconductor package, the second semiconductor package comprising:
a second redistribution structure comprising a first surface and a second surface that are opposite to each other, the second redistribution structure further comprising a second conductive pad on the first surface;
a second passivation layer on the first surface of the second redistribution structure, the second passivation layer including a second opening exposing a portion of the second conductive pad;
a conductive bump on the second passivation layer;
a second semiconductor chip on the second surface of the second redistribution structure; and
a second encapsulant on the second surface of the second redistribution structure and encapsulating at least a portion of the second semiconductor chip,
wherein the first conductive pad comprises:
a first edge area covered by the first passivation layer; and
a second edge area exposed by the first opening of the first passivation layer and separated from the first passivation layer, and
wherein the conductive bump fills at least part of each of the first opening and the second opening.

18. The package on package of claim 17, wherein the second conductive pad comprises:
a third edge area covered by the second passivation layer; and
a fourth edge area exposed by the second opening in the second passivation layer and spaced from the second passivation layer.

19. The package on package of claim 18, wherein the second edge area and the fourth edge area vertically overlap each other.

20. The package on package of claim 17, wherein the first semiconductor chip comprises a logic chip, and
wherein the second semiconductor chip comprises a memory chip.
